(19) United States
(12) Patent Application Publication
(10) Pub. No.: US 2019/0056430 A1
(43) Pub. Date: Feb. 21, 2019

(54) PLANE CORRECTING DEVICE AND SEMICONDUCTOR TESTING APPARATUS INCLUDING THE SAME

(71) Applicant: Hermes-Epitek Corp., Taipei City (TW)

(72) Inventors: Po-Ju KU, Hsinchu County (TW); Wei-Ting CHEN, Tainan City (TW)

(21) Appl. No.: 15/915,942

(22) Filed: Mar. 8, 2018

(30) Foreign Application Priority Data
Aug. 21, 2017 (TW) 106128280

(51) Int. Cl. G01R 1/073; G01R 31/28

(52) U.S. Cl. CPC G01R 1/07378; G01R 31/2831

(57) ABSTRACT

A plane correcting device comprises a first base disposed on a test head of a semiconductor testing apparatus; a second base disposed on the prober stage of the semiconductor testing apparatus and opposite to the first base; a plurality of correcting rods disposed between the first base and the second base, wherein a protruding height of each correcting rods may be adjusted to correct the prober stage to a predetermined plane; and a plurality of fixing units disposed on the first base or the second base to fix relative position of the prober stage and the test head. The present invention also provides a semiconductor testing apparatus including the plane correcting device.

### BACKGROUND OF THE INVENTION

### 1. Field of the Invention

The present invention relates to a correcting device, particularly to a plane correcting device for a prober stage of a semiconductor testing apparatus and a semiconductor testing apparatus including the same.

### 2. Description of the Prior Art

In an ordinary semiconductor testing process, the test head of a semiconductor testing apparatus is electrically connected with the prober stage of the wafer prober before wafer test. In assembling the test head and the prober stage, the up-and-down movements of the test head may bring about a level error of the prober stage. The level error may cause imperfect contact between the prober stage and the tested object and lower the yield. The conventional solution is separating the test head from the prober stage and then recombining them to correct the level of the prober stage. The up-and down movement of the test head has a level error of about 50-200 μm. However, the acceptable level error is only about 15 μm. Therefore, the conventional correcting method is very time-consuming, taking about 1.5-2.5 hours each time.

Accordingly, a device able to fast correct the plane of the prober stage and decrease the level error thereof has been a target the related manufacturers are eager to achieve.

### SUMMARY OF THE INVENTION

The present invention provides a plane correcting device and a semiconductor apparatus including the same, wherein the plane correcting device is disposed between the test head and prober stage of the semiconductor testing apparatus, whereby the user can use the plane correcting device to fast align the prober stage to a predetermined plane.

In one embodiment, the present invention provides a plane correcting device, which comprises a first base disposed on a test head of a semiconductor testing apparatus; a second base disposed on a prober stage of the semiconductor testing apparatus and opposite to the first base; a plurality of correcting rods disposed between the first base and the second base, wherein the height by which each correcting rod protrudes may be adjusted to align the prober stage to a predetermined plane; and a plurality of fixing units disposed between the first base or the second base and used to fix the relative position of the prober stage and the test head.

In one embodiment, each correcting rod has a screw thread on the outer surface thereof.

In one embodiment, the first base extends out of the edges of the test head to form extension portions; the plurality of correcting rods penetrates the extension portions and presses against the second base.

In one embodiment, the plurality of fixing units is disposed on the second base.

In one embodiment, the plurality of fixing units fixes the relative position of the prober stage and the test head in at least one of a screwing method, a press-fit method and a clamping method.

In one embodiment, the first base is integrated with the test head.

In one embodiment, the second base is integrated with the prober stage.

In one embodiment, the present invention provides a semiconductor testing apparatus, which comprises a test head, a prober stage electrically connected with the test head, and a plane correcting device. The plane correcting device further comprises a first base disposed on the test head; a second base disposed on the prober stage and opposite to the first base; a plurality of correcting rods disposed between the first base and the second base, wherein the protruding height of each correcting rod (the length by which each correcting rod extends between the first base and the second base) may be adjusted to align the prober stage to a predetermined plane; and a plurality of fixing units disposed on the first base or the second base for fixing the relative position of the prober stage and the test head.

Below, embodiments are described in detail in cooperation with the attached drawings to make easily understood the objectives, technical contents, characteristics and accomplishments of the present invention.

### BRIEF DESCRIPTION OF THE DRAWINGS

FIG. 1A is a top view schematically showing a plane correcting device and a semiconductor apparatus including the same according to one embodiment of the present invention;

FIG. 1B is a side view schematically showing the plane correcting device and the semiconductor apparatus including the same shown in FIG. 1A;

FIG. 2A is a top view schematically showing a plane correcting device and a semiconductor apparatus including the same according to another embodiment of the present invention;

FIG. 2B is a side view schematically showing the plane correcting device and the semiconductor apparatus including the same shown in FIG. 2A;

FIG. 3A and FIG. 3B are diagrams schematically showing the operation of a plane correcting device according to one embodiment of the present invention.

### DESCRIPTION OF THE PREFERRED EMBODIMENTS

The present invention will be described in detail with embodiments and attached drawings below. However, these embodiments are only to exemplify the present invention but not to limit the scope of the present invention. In addition to the embodiments described in the specification, the present invention also applies to other embodiments. Further, any modification, variation, or substitution, which can be easily made by the persons skilled in that art according to the embodiment of the present invention, is to be also included within the scope of the present invention, which is based on the claims stated below. Although many special details are provided herein to make the readers more fully understand the present invention, the present invention can still be practiced under a condition that these special details are partially or completely omitted. Besides, the elements or steps, which are well known by the persons skilled in the art, are not described herein lest the present invention be limited unnecessarily. Similar or identical elements are denoted with similar or identical symbols in the drawings. It should be noted: the drawings are only to depict the present invention schematically but not to show the real dimensions or quantities of the present invention. Besides, matterless details are not necessarily depicted in the drawings to achieve conciseness of the drawings.

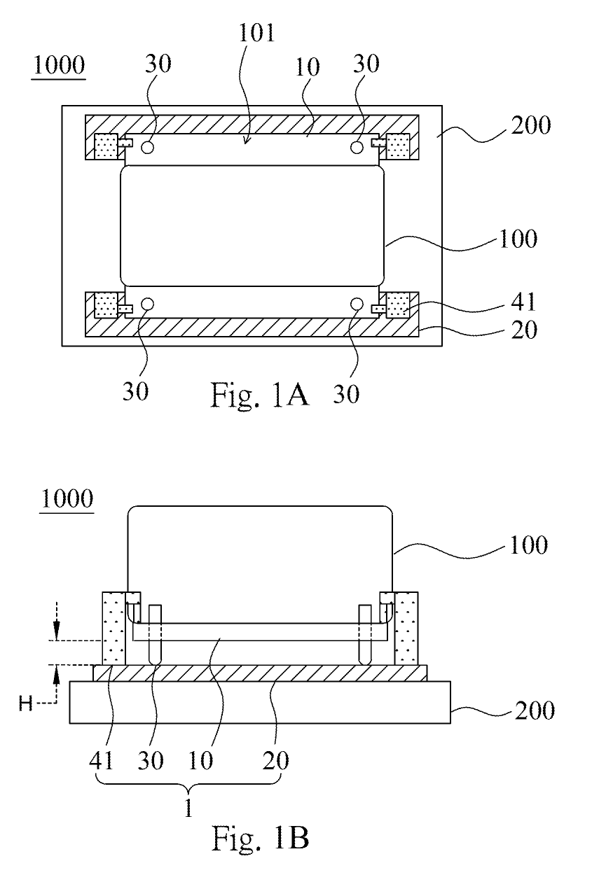

Refer to FIG. 1A and FIG. 1B respectively a top view and a side view schematically showing a plane correcting device and a semiconductor apparatus including the same according to one embodiment of the present invention. The plane correcting device 1 of the present invention comprises a first base 10, a second base 20, a plurality of correcting rods 30, and a plurality of fixing units 41. The first base 10 is disposed on a test head 100 of a semiconductor testing apparatus. The second base 20 is disposed on a prober stage 200 of the semiconductor testing apparatus and opposite to the first base 10. The plurality of correcting rods 30 is disposed between the first base 10 and the second base 20. The protruding height H of each correcting rod 30 (the length by which each correcting rod extends between the first base 10 and the second base 20) may be adjusted to align the prober stage 200 to a predetermined plane, as shown in FIG. 1B. In FIG. 1A, the plurality of correcting rods are exemplified by four correcting rods 30. However, the present invention does not particularly limit the number of the correcting rods. The number of the correcting rods may be adjusted according to requirement in the present invention.

In one embodiment, the first base 10 of the plane correcting device 1 extends out of the edges of the test head 100 to form extension portions 101, as shown in FIG. 1A. The plurality of correcting rods 30 penetrates the extension portions 101 and presses against the second base 20, as shown in FIG. 1B. In one embodiment, each correcting rod 30 has a screw thread on the outer surface thereof. The screw thread is a continuous protruding incline spiraling the outer surface of the correcting rod 30. The protruding height H of the correcting rod 30 can be adjusted via rotating the thread of the correcting rod 30. The operation of using the correcting rods 30 to calibrate the prober stage will be described in detail thereinafter.

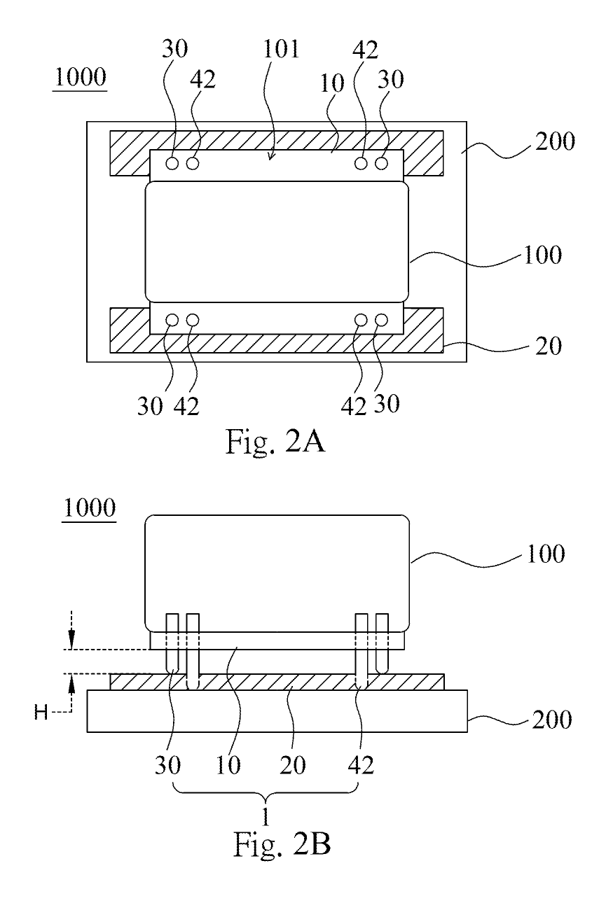

The plurality of fixing units 41 of the plane correcting device 1 is disposed on the first base 10 or the second base 20 for fixing the relative position of the prober stage 200 and the test head 100. In FIG. 1A and FIG. 1B, the fixing units 42 fix the relative position of the prober stage 200 and the test head 100 in a clamping way. However, the present invention does not particularly limit the way to fix the relative position of the prober stage 200 and the test head 100. The relative position of the prober stage 200 and the test head 100 may be fixed in other ways in the present invention. Refer to FIG. 2A and FIG. 2B respectively a top view and a side view schematically showing a plane correcting device and a semiconductor apparatus including the same according to another embodiment of the present invention. In one embodiment, the plurality of fixing units 41 is disposed on the second base 20, fastening the prober stage 200 and the test head 100 together and fixing the relative position thereof in a screwing way or a press-fit way. In FIG. 1A and FIG. 2A, the fixing units are exemplified by four fixing units 41 and four fixing units 42 respectively. However, the present invention does not particularly limit the number of the fixing units. In the present invention, the number of the fixing units may be adjusted to fix the relative position of the prober stage and the test head according to requirement. Besides, the present invention does not particularly limit the way that the fixing units use to fix the prober stage and the test head. In one embodiment, the fixing units undertake fixing in at least one of a screwing method, a press-fit method and a clamping method. In other words, the fixing units of the plane correcting device of the present invention can undertake fixing in two or three methods simultaneously.

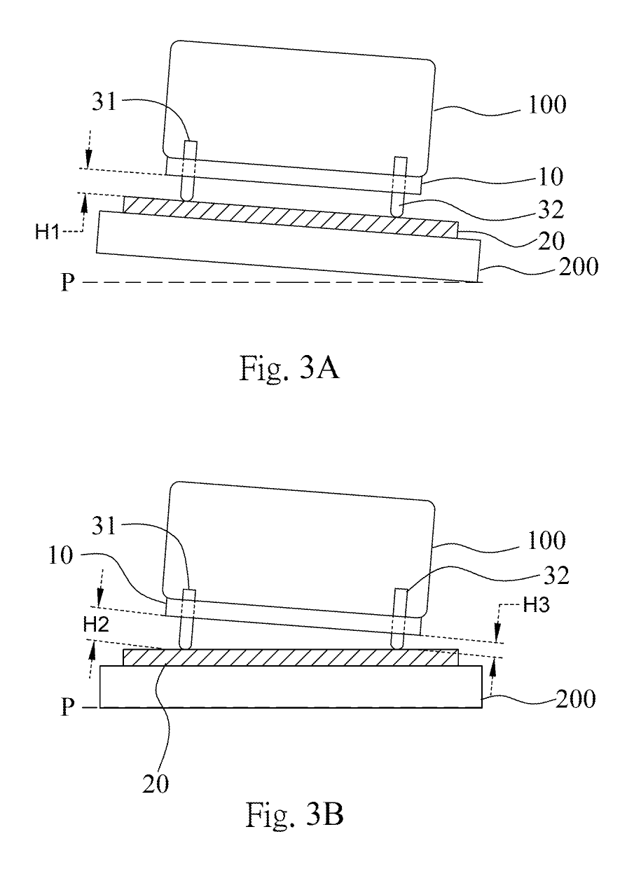

Refer to FIG. 3A and FIG. 3B diagrams schematically showing the operation of a plane correcting device according to one embodiment of the present invention. While the prober stage 200 is assembled to the test head 100, the up-and down movements of the test head 100 or other factors may bring about a level error of the prober stage 200 with respect to a predetermined plane P. In one embodiment, the protruding heights of the correcting rods can be adjusted via rotating the screw threads of the correcting rods. In FIG. 3A and FIG. 3B, the correcting rods 31 and 32 are operated to adjust the original protruding height H1 to be the protruding heights H2 and H3, wherein the protruding height H2 may be different from the protruding height H3. In the embodiment shown in FIG. 3A and FIG. 3B, the protruding height H2 is larger than the protruding height H3. However, the present invention is not limited by this embodiment. The user may arbitrarily adjust the protruding heights of the correcting rods according to the level error of the prober stage 200 with respect to the predetermined plane P.

In one embodiment that is not shown in the attached drawings, the first base of the plane correcting device of the present invention is integrated with the test head. In other words, the test head includes the first base, and the correcting rods directly penetrate the first base of the test head. In one embodiment that is not shown in the attached drawings, the second base of the plane correcting device of the present invention is integrated with the prober stage. In other words, the prober stage includes the second base, and the correcting rods press against the second base of the prober stage.

Refer to FIGS. 1A, 1B, 2A and 2B again. In one embodiment, the present invention further provides a semiconductor testing apparatus 1000, which comprises a test head 100, a prober stage 200 electrically connected with the test head 100, and a plane correcting device 1. The plane correcting device 1 further comprises a first base 10, a second base 20, a plurality of correcting rods 30, and a plurality of fixing units 41. The components and operation of the plane correcting device 1 have been described above and will not repeat herein. It is easily understood: the semiconductor testing apparatus 1000 still requires other components, such as a control unit and the loading/unloading units, which are familiar to the persons skilled in the art and not the technical characteristics of the present invention. Therefore, they will not repeat herein.

In conclusion, the present invention provides a plane correcting device and a semiconductor testing apparatus including the same. The present invention can easily align the prober stage to a predetermined plane with a level error below 15 μm via adjusting the protruding heights of the correcting rods, neither disassembling nor reassembling the test head. Decreasing the level error can improve the imperfect contact between the prober stage and the tested object (not shown in the drawings). In comparison with the conventional adjusting technology, the present invention can greatly increase the yield of wafer test in a simple and fast way.

What is claimed is:

1. A plane correcting device comprising
a first base disposed on a test head of a semiconductor testing apparatus;
a second base disposed on a prober stage of the semiconductor testing apparatus and opposite to the first base;
a plurality of correcting rods disposed between the first base and the second base, wherein a protruding height of each correcting rod is adjustable to align the prober stage to a predetermined plane, wherein the protruding height of each correcting rod is a length of each correcting rod extends between the first base and the second base; and
a plurality of fixing units disposed on the first base or the second base for fixing the relative position of the prober stage and the test head.

2. The plane correcting device according to claim 1, wherein each correcting rod has a screw thread on the outer surface thereof.

3. The plane correcting device according to claim 1, wherein the first base extends out of edges of the test head to form extension portions, and wherein the plurality of correcting rods penetrates the extension portions and presses against the second base.

4. The plane correcting device according to claim 1, wherein the plurality of fixing units is disposed on the second base.

5. The plane correcting device according to claim 1, wherein the plurality of fixing units fixes the relative position of the prober stage and the test head in at least one of a screwing method, a press-fit method and a clamping method.

6. The plane correcting device according to claim 1, wherein the first base is integrated with the test head.

7. The plane correcting device according to claim 1, wherein the second base is integrated with the prober stage.

8. A semiconductor testing apparatus comprising
a test head;
a prober stage electrically connected with the test head; and
a plane correcting device including
a first base disposed on the test head;
a second base disposed on the prober stage and opposite to the first base;
a plurality of correcting rods disposed between the first base and the second base, wherein a protruding height of each correcting rod is adjustable to align the prober stage to a predetermined plane, wherein the protruding height of each correcting rod is a length of each correcting rod extends between the first base and the second base; and
a plurality of fixing units disposed on the first base or the second base for fixing the relative position of the test head and the prober stage.

9. The semiconductor testing apparatus according to claim 8, wherein each correcting rod has a screw thread on the outer surface thereof.

10. The semiconductor testing apparatus according to claim 8, wherein the first base extends out of edges of the test head to form extension portions, and wherein the plurality of correcting rods penetrates the extension portions and presses against the second base.

11. The semiconductor testing apparatus according to claim 8, wherein the plurality of fixing units is disposed on the second base.

12. The semiconductor testing apparatus according to claim 8, wherein the plurality of fixing units fixes the relative position of the prober stage and the test head in at least one of a screwing method, a press-fit method and a clamping method.

13. The semiconductor testing apparatus according to claim 8, wherein the first base is integrated with the test head.

14. The semiconductor testing apparatus according to claim 8, wherein the second base is integrated with the prober stage.
